(19) United States
(12) Patent Application Publication
(10) Pub. No.: US 2010/0084667 A1
(43) Pub. Date: Apr. 8, 2010

(54) Semiconductor Light Source Element for Beam Forming

(76) Inventors: James R. Mcfadden, Oxford, MI (US); Ronald O. Woodward, Yorktown, VA (US); Ronald G. Hare, Ontario (CA)

Correspondence Address: MAGNA INTERNATIONAL, INC., 337 MAGNA DRIVE, AURORA, ON, L4G-7K1, CA

(21) Appl. No.: 12/524,190

(22) PCT Filed: Jan. 25, 2008
(86) PCT No.: PCT/CA08/00139

§ 371 Date: Aug. 14, 2009

Related U.S. Application Data
(60) Provisional application No. 60/897,352, filed on Jan. 25, 2007.

(51) Int. Cl. H01L 33/00

(52) U.S. Cl. 257/88; 257/98; 257/E33.068

(57) ABSTRACT

A semiconductor light source element includes a substrate to which at least one semiconductor light source is mounted. An optical body is mounted to the substrate with its light receiving surface located adjacent the light emitting surface of the at least one semiconductor light source. The optical body has a shape and light output surface profile which are selected to produce a desired beam pattern with the light emitted by the at least one semiconductor light source. When two or more semiconductor light sources are employed in the semiconductor light source element, the light sources can be positioned at different locations about the light receiving surface to emit light from the front edge of the optical body in correspondingly diverse patterns.

### FIELD OF THE INVENTION

The present invention relates to a light source element which can be useful in constructing desired beam patterns of light. More specifically, the present invention relates to a light source element employing semiconductor light sources.

### BACKGROUND OF THE INVENTION

Light emitting semiconductors, such as light emitting diodes (LEDs), can now produce white light at sufficient levels so that semiconductor light sources can be used instead of incandescent or gas discharge lamps to create lighting systems such as vehicular headlamps and signaling lamps.

However, while the creation of such semiconductor-based lighting systems is possible, the light output of the semiconductor light sources is still much less than conventional incandescent and gas discharge lamps and conventional lighting system designs, intended for these prior art light sources with much higher light output levels, are too inefficient at making use of the light emitted from semiconductor light sources.

Accordingly, it is desired to have a light source element which makes efficient use of the light emitted from semiconductor light sources and which forms that light into a beam which is useful for producing a desired light pattern.

### SUMMARY OF THE INVENTION

It is an object of the present invention to provide a novel semiconductor light source element for beam forming which obviates or mitigates at least one disadvantage of the prior art.

According to a first aspect of the present invention, there is provided a semiconductor light source element comprising: at least one semiconductor light source having a light emitting surface; an optical body having a light receiving surface and a light output surface, the optical body being mounted with respect to the at least one semiconductor light source such that the light receiving surface is adjacent the light emitting surface of the at least one semiconductor light source and the body being shaped such that the light emitted from the light emitting surface is received by the light receiving surface and is focused by the optical body such that it is emitted from the light output surface in a desired beam pattern Preferably, the semiconductor light source element includes three semiconductor light sources, the light emitting surface of two of the three semiconductor light sources being located at the same vertical level adjacent the light receiving surface while the light emitting surface of the third of the three semiconductor light sources being located at a different vertical level adjacent the light receiving surface, the third semiconductor light source being selectively operable to add or remove a vertical component to the desired beam pattern emitted by the front edge.

The present invention provides a semiconductor light source element that includes at least one semiconductor light source and an optical body mounted with its light receiving surface located adjacent the light emitting surface of the at least one semiconductor light source. The optical body has a shape and light output surface profile which are selected to produce a desired beam pattern with the light emitted by the at least one semiconductor light source. When two or more semiconductor light sources are employed in the semiconductor light source element, the light sources can be positioned at different locations about the light receiving surface to emit light from the front edge of the optical body in correspondingly diverse patterns.

### BRIEF DESCRIPTION OF THE DRAWINGS

Preferred embodiments of the present invention will now be described, by way of example only, with reference to the attached Figures, wherein:

FIG. 1 shows a side view of a semiconductor light source element in accordance with the present invention;

FIG. 2 shows a perspective view of the side and front of the semiconductor light source element of FIG. 1;

FIG. 3 shows a rear view of the optical body of the semiconductor light source element of FIG. 1 with the substrate removed;

FIGS. 4a, 4b and 4c show sections taken along lines 4a-4a, 4b-4b and 4c-4c, respectively, in FIG. 1; and

FIG. 5 shows a detailed view of the light receiving surface of the optical body and the semiconductor light sources of the semiconductor light source element of FIG. 1.

### DETAILED DESCRIPTION OF THE INVENTION

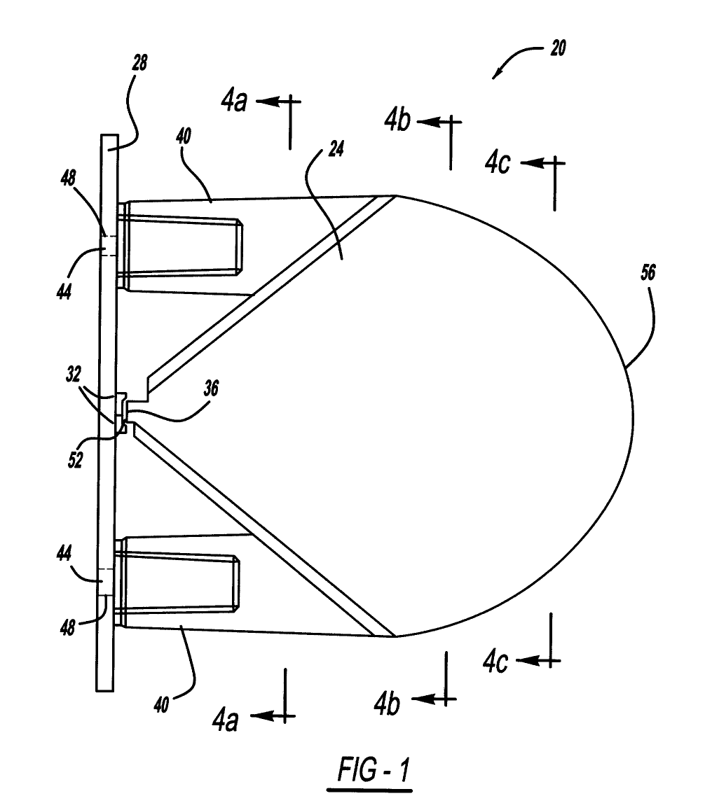

A semiconductor light source element, in accordance with the present invention, is indicated generally at 20 in FIGS. 1, 2 and 3. Light source element 20 includes a substantially transparent optical body 24, which has a generally “D” shaped profile when viewed from the side, as in FIG. 1. Optical body 24 can be formed of any suitable material and by any suitable means, as will occur to those of skill in the art. In a present embodiment, optical body 24 is formed by injection molding of Acrymid, manufactured by CYRO Ltd.

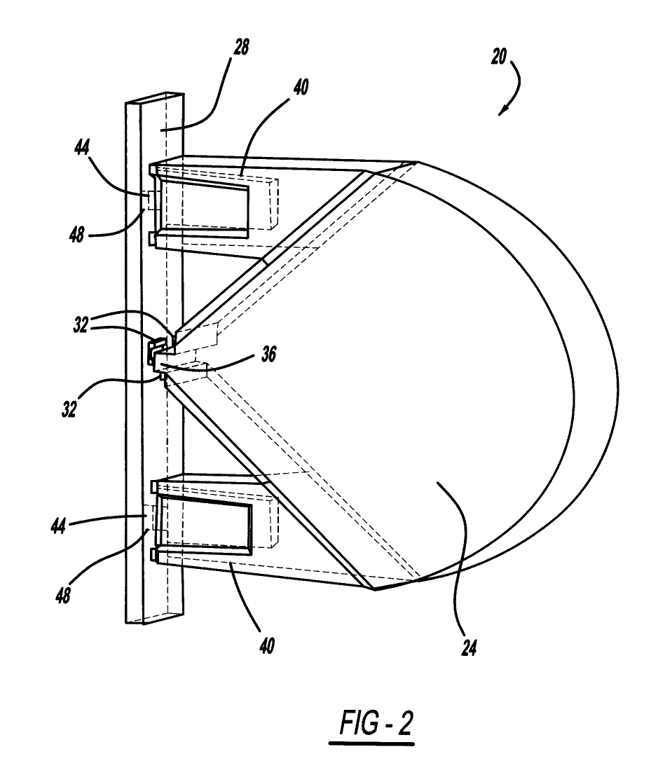

Optical body 24 is mounted to a substrate 28, shown in FIGS. 1 and 2, such as a printed circuit board, which has one or more semiconductor light sources 32 operatively mounted to it with their light emitting surfaces facing away from the surface of substrate 28. Substrate 28 includes appropriate electrical traces (not shown) to supply power to semiconductor light sources 32 and can include features such as layers of copper or other materials, thermal vias, etc. which assist in the transfer of waste heat from semiconductor light sources 32.

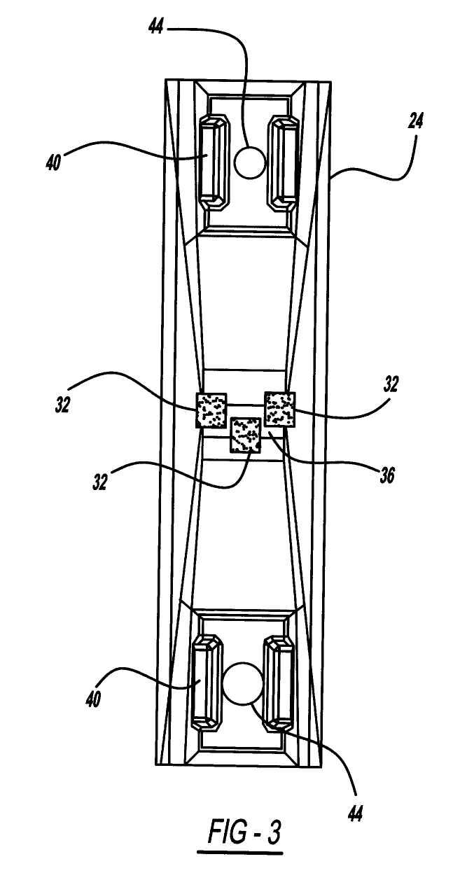

Optical body 24 includes a light receiving surface 36, which is located with respect to the light emitting surfaces of semiconductor light sources 32 by a pair of mounting legs 40. Each mounting leg 40 includes a locator pin 44 which engages a complementary aperture 48 in substrate 28 to position light receiving surface 36 with respect to the light emitting surfaces of semiconductor light sources 32. As best seen in FIG. 3, locator pins 44 can be different sized, with their respective intended apertures 48 in substrate 28 being correspondingly sized, to ensure that optical body 24 is positioned in the correct orientation with respect to substrate 28.

Once optical body 24 is correctly positioned on substrate 28, mounting legs 40 can then be permanently fastened to substrate 28 by any suitable means, such as by gluing, to fix the positioning of light receiving surface 36 with respect to semiconductor light sources 32. As shown in FIG. 1, mounting legs 40 are sized such that, when optical body 24 is correctly positioned, light receiving surface 36 is spaced from the light emitting surfaces of semiconductor light sources 32 by an air gap 52. Air gap 52 is provided to allow refraction to occur at light receiving surface and this refraction ensures that the rays of received light enter at no more than a forty five degree angle, thus ensuring that all of the received light experiences total internal refraction within optical body 24. Air gap 52 also provides a thermal separation between light receiving surface 36 and the light emitting surfaces of semiconductor light sources 32.

In the illustrated embodiment, three semiconductor light sources 32 (best seen in FIG. 3 where their respective positioned are indicated by the stippled areas) are mounted on substrate 28 in a staggered formation with the two outside semiconductor light sources 32 are positioned at one level and the inner semiconductor light source 32 is positioned at another level.

As mentioned above, optical body 24 is generally D-shaped when viewed from the side. Light entering optical body 24 through light receiving surface 36 is emitted from the light output surface, in this embodiment front edge 56, of optical body 24 such that it is vertically (with reference to the orientation of optical body 24 shown in FIGS. 1 and 2) constrained and horizontally spread. The degree of constraint and the amount of the horizontal spread depend upon the profile of front edge 56 and the shape of the sides 60 of optical body 24. In the illustrated embodiment, front edge 56 has a regular circular (when viewed from the side as in FIG. 1) profile but the present invention is not limited to the use of such regular circular profiles and other profiles, such as oval or truncated (i.e.—including flattened surfaces) circular profiles, can be employed as desired to obtain a desired vertical constraint for the light emitted by semiconductor light source element 20.

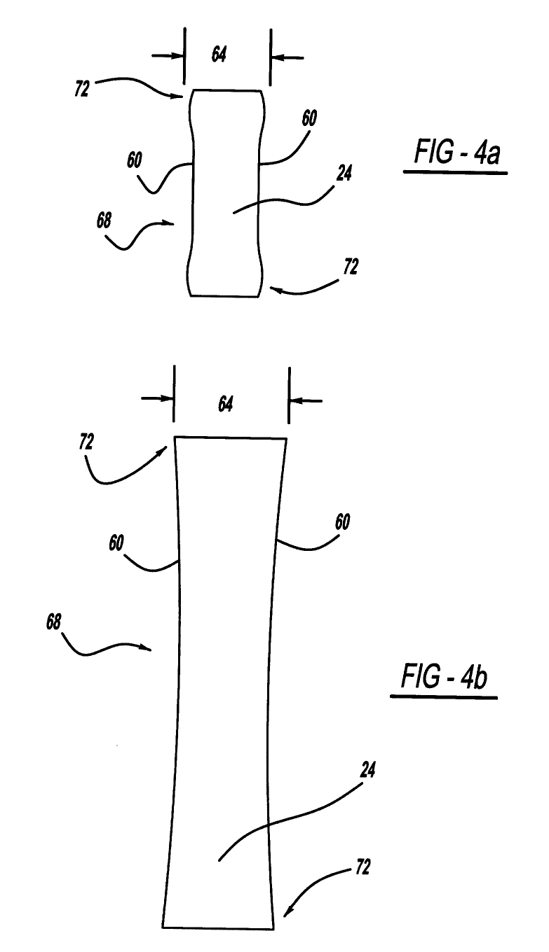

When semiconductor light source element 20 is intended to produce spread light (as opposed to “hot spot” light) in an automotive headlamp pattern, it is desired to have a sharp vertical constraint for the light emitted from front edge 56, especially at the center of the light pattern emitted from front edge 56. Accordingly, in an embodiment of the present invention intended for such uses, sides 60 of the optical body 24 are shaped to have a tapering complex shape, as indicated in FIGS. 4a, 4b and 4c.

As shown, the average thickness 64 (i.e.—the distance between sides 60 of optical body 24) increases with the distance from light receiving surface 36 towards front edge 56. Further, as shown, the thickness is not constant at cross sections through optical body 24, with a lesser thickness at the vertical center 68 of optical body 24 than the thickness 72 adjacent the top or bottom of optical body 24.

By increasing the average thickness 64 of optical body 24 from a first thickness adjacent light receiving surface 36 to a second, greater, thickness adjacent front edge 56, the light emitted from front edge 56 will be more horizontally constrained than if optical body 24 had a constant thickness.

The vertical changing of the thickness, at each section along optical body 24, from a minimum thickness at center 68 to a maximum thickness adjacent edges 72, enhances the control provided by the profile of the light output surface (the curved portion of the D-shaped profile) which focuses the light at the center of the emitted pattern to a sharp cutoff. Wide angle rays will exit at increasing vertical angles as the exit angle increases. By curving the vertical side walls, this effect can be reduced or completely corrected.

As will be apparent to those of skill in the art, the particular design of the shape of sides 60 of optical body 24 can be varied to obtain a wide range of constraints to the light emitted from front edge 56 as may be desired for other applications of semiconductor light source element 20.

Semiconductor light sources 32 act much like point sources of light and thus their positioning relative to light receiving surface 36 and front edge 56 results in their respective emitted light creating different patterns from optical body 24. In the illustrated embodiment, the two semiconductor light sources 32 located at the same vertical height are used to produce spread light for an automotive low beam headlamp pattern. In particular, these semiconductor light sources 32 act as Lambertian area sources with sharply defined edges. One edge of the semiconductor light sources 32 is vertically imaged (focused) by optical body 24 to emphasize that edge and to thereby achieve the desired a high gradient cutoff for use in an automotive low beam pattern.

The one semiconductor light source 32 located at the lower vertical height is used to add additional spread light for an automotive high beam headlamp pattern.

The difference in the vertical heights of the semiconductor light sources 32, results in the corresponding light (and respective gradients) emitted from front edge 56 being at different heights, as desired for proper construction of the headlamp patterns. As the semiconductor light source 32 used for the high beam is lower, with respect to light receiving surface 36, than the semiconductor light sources 32 used for the low beam, the light from the high beam semiconductor light source 32 emitted from front edge 56 is aimed higher the light from the low beam semiconductor light sources 32.

Thus, by providing a vertical difference in the location of the semiconductor light sources 32, the light emitted from front edge 56 can effectively be moved vertically without requiring any moving parts in the optics of the headlamp system.

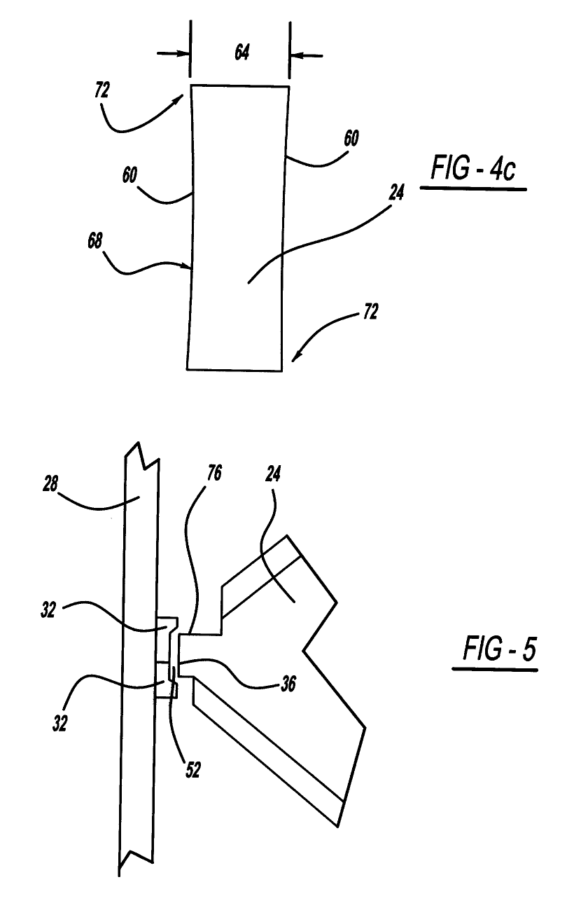

Referring now to FIG. 5, more detail of light receiving surface 36 and its surrounding area can be seen. As shown, a blending surface 76 is provided adjacent light receiving surface 36 and the two semiconductor light sources 32 used to create low beam spread light. Due to the total internal reflection of light entering optical body 24 through light receiving surface 36 from the light emitting surface of semiconductor light sources 32, blending surface 76 acts to vertically shape the distribution of the light from the semiconductor light sources 32 used to create low beam spread light. In a present embodiment of the invention, it has been found that a blending surface of about two millimeters provides a good vertical distribution of the light from these two semiconductor light sources 32.

While in the discussion above only three semiconductor light sources 32 have been discussed, the present invention is not so limited and one, two or more than three semiconductor light sources 32 can be employed, if desired. For example one or more additional semiconductor light sources 32 can be positioned adjacent light receiving surface 36 to provide for Fog Lamp or Driving Lamp functionality. Similarly, a single semiconductor light source 32 can be employed with light source element 20 if light source element is, for example, only intended to provide high beam spread light.

The present invention is believed to provide numerous advantages over prior art attempts to employ semiconductor light sources to create light source elements useful in creating desired beam patterns. In particular, some prior art systems employed light pipes to transfer light received from the semiconductor light source to the beam forming optical body. Due to the resulting long optical path through the light pipe and optical body of such systems, any impurities in the materials from which the light path is constructed result in the dispersion of the light, reducing the efficiency of the light source element. Similarly, any optical defects in the optical path, such as molding artifacts due to shear stress, irregular melt flows or the like, also result in dispersion of the light and a reduced efficiency of the light source element.

By removing the need for a light pipe, and thus reducing the overall length of the optical path, the present invention reduces or avoids these problems.

Further, by eliminating the need for the light pipe, the present invention provides substantially direct vertical imaging of the semiconductor light sources, allowing the emitted light patterns to be selectively formed by illuminating and extinguishing vertically positioned semiconductor light sources and allowing for edges of the semiconductor light sources to be imaged, providing for sharp gradients if desired. Also, the provision of an appropriate blending surface can allow the vertical distribution of light emitted from the font edge of the optical body to be shaped as desired.

The present invention provides a semiconductor light source element that includes at least one semiconductor light source and an optical body, which is mounted with its light receiving surface located adjacent the light emitting surface of the at least one semiconductor light source. The optical body has a shape and light output surface profile which are selected to produce a desired beam pattern with the light emitted by the at least one semiconductor light source. When two or more semiconductor light sources are employed in the semiconductor light source element, the light sources can be positioned at different locations about the light receiving surface to emit light from the front edge of the optical body in correspondingly diverse patterns.

The above-described embodiments of the invention are intended to be examples of the present invention and alterations and modifications may be effected thereto, by those of skill in the art, without departing from the scope of the invention which is defined solely by the claims appended hereto.

We claim:

1. A semiconductor light source element comprising:
at least one semiconductor light source having a light emitting surface; and
an optical body having a light receiving surface and a light output surface, said optical body being mounted with respect to said at least one semiconductor light source such that said light receiving surface is adjacent said light emitting surface of said at least one semiconductor light source, said optical body being shaped such that the light emitted from said light emitting surface is received by said light receiving surface and is focused by said optical body such that it is emitted from said light output surface in a desired beam pattern.

2. The semiconductor light source element according to claim 1, wherein said at least one semiconductor light source is mounted to a substrate having a set of electrical traces, said at least one semiconductor light source being operatively connected to said electrical traces and said optical body also being mounted to said substrate.

3. The semiconductor light source element of claim 1, said at least one semiconductor light source further comprising:
at least three semiconductor light sources, said light emitting surface of two of said at least three semiconductor light sources being located at the same vertical level adjacent said light receiving surface while said light emitting surface of said third of said at least three semiconductor light sources being located at a different vertical level adjacent said light receiving surface, said third semiconductor light source being selectively operable to add or remove a vertical component to the desired beam pattern emitted by said light output surface.

4. The semiconductor light source element of claim 1, further comprising at least one blending surface on said optical body adjacent said light receiving surface, said at least one blending surface operable to shape the vertical distribution of the light emitted from said light output surface.

5. The semiconductor light source element of claim 1, said at least one blending surface further comprising a plurality of blending surfaces on said optical body adjacent said light receiving surface, further shaping the vertical distribution of the light emitted from said light output surface.

6. The semiconductor light source element of claim 1, said at least one semiconductor light source further comprising:
at least two semiconductor light sources, said light emitting surface of one of said at least two semiconductor light sources being located at a different vertical level, adjacent said light receiving surface, from said light emitting surface of the second of said at least two semiconductor light sources, said second semiconductor light source being selectively operable to add or remove a vertical component to the desired beam pattern emitted by said light output surface.

7. The semiconductor light source element of claim 1, said light output surface of said optical body further comprising a front edge.

8. The semiconductor light source element of claim 7, wherein the shape of said front edge is one selected from the group consisting of: a D-shape, oval, truncated, circular, or combinations thereof.

9. The semiconductor light source element of claim 1, said light output surface of said optical body further comprising a thickness which varies between a minimum thickness at substantially the center of said optical body, to a maximum thickness at the outer region of said optical body, thereby enhancing the control provided by the profile of said light output surface.

10. A semiconductor light source element, comprising:
a substrate;
at least one semiconductor light source mounted on said substrate;
a light emitting surface formed as a portion of said at least one semiconductor light source, said light emitting surface facing in a direction away from said substrate; and
an optical body having a light receiving surface and a light output surface, said light receiving surface being adjacent said light emitting surface of said at least one semiconductor light source, and said optical body is shaped such that said light receiving surface receives light from said light emitting surface and said optical body focuses light emitting from said light output surface in a desired beam pattern.

11. The semiconductor light source element of claim 10, said at least one semiconductor light source further comprising a plurality of semiconductor light sources.

12. The semiconductor light source element of claim 11, further comprising each of said plurality of semiconductor light sources having a light emitting surface, and said light emitting surface of two of said plurality of semiconductor light sources being offset from the light emitting surface of another of said plurality of semiconductor light sources adjacent said light receiving surface.

13. The semiconductor light source element of claim 12, further comprising one of said plurality of semiconductor light sources and being selectively operable to add or remove a vertical component of the desired beam pattern emitted by said light output surface.

14. The semiconductor light source element of claim 11, further comprising each of said plurality of semiconductor light sources having a light emitting surface, and said light emitting surface of one of said plurality of semiconductor light sources adjacent said light receiving surface and offset from another of said plurality of semiconductor light sources.

15. The semiconductor light source element of claim 14, further comprising one of said plurality of semiconductor light sources and being selectively operable to add or remove a vertical component of the desired beam pattern emitted by said light output surface.

16. The semiconductor light source element of claim 10, further comprising:
a blending surface located substantially perpendicular in relation to said light receiving surface, said blending surface being operable to shape the vertical distribution of the light emitted from the light output surface.

17. The semiconductor light source element of claim 10, said optical body further comprising:
a front edge formed as a portion of said light output surface; and
a thickness which varies between a minimum thickness at substantially the center of the optical body, to a maximum thickness at the outer region of said optical body, thereby enhancing the control provided by the profile of said front edge.

18. The semiconductor light source element of claim 17, wherein the shape of said front edge is one selected from the group consisting of: a D-shape, oval, truncated, flat, circular, or combinations thereof.

19. A semiconductor light source element, comprising:
at least one semiconductor light source mounted on a substrate;
a light emitting surface formed as a portion of said at least one semiconductor light source;
an optical body operable for directing light received from said at least one semiconductor light source;
a light receiving surface formed as part of said optical body adjacent to, and able to receive light from, said light emitting surface; and
a light output surface formed as part of said optical body, and said optical body is shaped such that light received by said light receiving surface is directed by said optical body such that light is emitted from said light output surface in a desired beam pattern.

20. The semiconductor light source element of claim 19, further comprising a blending surface positioned substantially perpendicularly to said light receiving surface, said blending surface being operable to shape the vertical distribution of the light emitted from the light output surface.

21. The semiconductor light source element of claim 19, said at least one semiconductor light source further comprising a plurality of semiconductor light sources, wherein at least one of said plurality of semiconductor light sources is offset from the rest of said plurality of semiconductor light sources and is selectively operable to add or remove a vertical component of the desired beam pattern emitted by said light output surface.

22. The semiconductor light source element of claim 19, said light output surface of said optical body further comprising a front edge, wherein the thickness of said optical body varies between a minimum thickness at substantially the center of the optical body, to a maximum thickness at the outer region of said optical body, thereby enhancing the control provided by the profile of said front edge.

23. The semiconductor light source element of claim 22, wherein the shape of said front edge is one selected from the group consisting of: a D-shape, oval, truncated, circular, or combinations thereof.
